(19) United States
(12) Patent Application Publication
(10) Pub. No.: US 2026/0005119 A1
(43) Pub. Date: Jan. 1, 2026

(54) COAXIAL THROUGH-INSULATOR VIA (TIV) WITH LATERAL METAL FOOTING CONNECTION FOR CHIPLET POWER SIGNAL CONNECTION

(71) Applicant: International Business Machines Corporation, Armonk, NY (US)

(72) Inventors: Tsung-Sheng Kang, Ballston Lake, NY (US); Tao Li, Slingerlands, NY (US); Qianwen Chen, Chappaqua, NY (US); Joshua M. Rubin, Albany, NY (US); Ruilong Xie, Niskayuna, NY (US)

(21) Appl. No.: 18/755,348

(22) Filed: Jun. 26, 2024

(51) Int. Cl. H01L 23/498; H01L 23/00; H01L 23/66; H01L 25/065

(52) U.S. Cl. CPC H01L 23/49838; H01L 23/49816; H01L 23/66; H01L 24/13; H01L 24/29; H01L 24/73; H01L 25/0655; H01L 2223/6622; H01L 2224/13009; H01L 2224/13025; H01L 2224/29005; H01L 2224/29021; H01L 2224/73103; H01L 2924/1434; H01L 2924/15311; H01L 2924/182

(57) ABSTRACT

A semiconductor structure includes a first wiring region including interconnected first metal lines and first vias; an insulator outward of same; and a first circuitry element, located in the insulator, and connected to at least a first one of the first vias. A coaxial through dielectric via is located in the insulator, which includes an inner conductor, a dielectric layer surrounding the inner conductor, and an outer conductor outward of the dielectric layer. The outer conductor includes inner and outer footing structures. A second wiring region is outward of the insulator, and includes a signal line connected to the inner conductor and a power line connected to the outer footing structure. The inner conductor is connected to at least a second one of the first vias and the inner footing structure is connected at least a third one of the first vias.

### BACKGROUND

The present invention relates generally to the electrical, electronic and computer arts and, more particularly, to packaging of integrated circuits including use of through-insulator vias (TIVs).

Noise coupling of through glass (insulator) vias has recently been explored in the literature. The low loss characteristics of these materials can be of concern, however, and the signal is typically not strongly attenuated in the material.

### BRIEF SUMMARY

Principles of the invention provide techniques for coaxial TIVs with a lateral metal footing connection for chiplet power signal connection. In one aspect, an exemplary semiconductor structure includes a first wiring region including a plurality of interconnected first metal lines and first vias; an insulator portion outward of the first wiring region; a first circuitry element, located in the insulator portion, and connected to at least a first one of the first vias in the first wiring region; a coaxial through dielectric via located in the insulator portion, the coaxial through dielectric via including an inner conductor, a dielectric layer surrounding the inner conductor, and an outer conductor outward of the dielectric layer, the outer conductor including inner and outer footing structures; and a second wiring region outward of the insulator portion, the second wiring region including a signal line connected to the inner conductor and a power line connected to the outer footing structure of the outer conductor. The inner conductor is connected to at least a second one of the first vias in the first wiring region and the inner footing structure of the outer conductor is connected at least a third one of the first vias in the first wiring region.

In another aspect, an exemplary method of forming a semiconductor structure includes providing an initial structure including a carrier wafer, a sacrificial layer outward of the carrier, an insulator region outward of the sacrificial layer, a first circuitry element in the insulator region, and a metal layer outward of the insulator region; using a first patterned mask, etching to produce a through dielectric via formation region in the metal layer and the insulator region, and a first footing formation region in the sacrificial layer; metallizing the first footing formation region and walls of the through dielectric via formation region to produce an outer conductor; forming a dielectric layer on the metallized walls of the through dielectric via formation region; forming a through dielectric via inner conductor within the dielectric layer on the metallized walls, and, using a second patterned mask, etching to produce second footings from the metal layer; and forming a first supplemental wiring region outward of the metal layer and the insulator region, with connections to the first circuitry element, the inner conductor, and the outer conductor.

In still another aspect, another exemplary method of forming a semiconductor structure includes providing an initial structure including a carrier wafer, a sacrificial layer outward of the carrier, an insulator region outward of the sacrificial layer, and a metal layer outward of the insulator region; using a first patterned mask, etching to produce a through dielectric via formation region in the metal layer and the insulator region, and a first footing formation region in the sacrificial layer; metallizing the first footing formation region and walls of the through dielectric via formation region to produce an outer conductor; forming a dielectric layer on the metallized walls of the through dielectric via formation region; forming a through dielectric via inner conductor within the dielectric layer on the metallized walls, and, using a second patterned mask, etching to produce second footings from the metal layer; forming a trench in the insulator region and locating a first circuitry element in the trench; and forming a first supplemental wiring region outward of the metal layer and the insulator region, with connections to the first circuitry element, the inner conductor, and the outer conductor.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor and/or by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
continuous and complete shielding provided by coaxial features;
Lateral, horizontal footing that extends away from the TIV and can help the connection because of wider area, and which also helps with mitigation of the noise from an immediate source.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1-13 show aspects of a process flow, in accordance with aspects of the invention, wherein FIG. 8 shows an alternative “trench” approach;

FIGS. 14-19 show exemplary process steps subsequent to the steps of FIGS. 1-13, according to an exemplary embodiment;

FIGS. 20-23 show exemplary process steps subsequent to the steps of FIGS. 1-13, according to another exemplary embodiment; and

FIG. 24 shows a cross-section through the via perpendicular to the long axis thereof, and is equally applicable to both exemplary embodiments.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

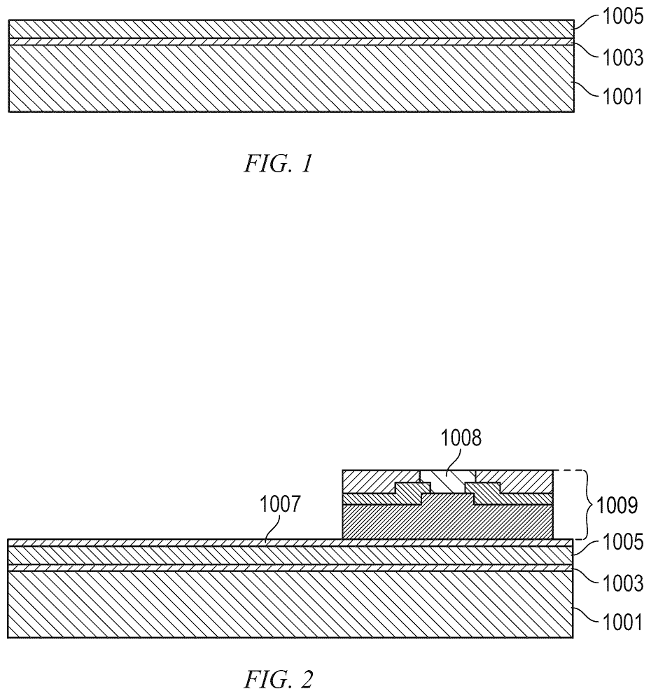

One or more embodiments provide coaxial TIVs with a lateral metal footing connection for chiplet power signal connection and techniques for fabricating same. An exemplary process flow will now be described, beginning with FIG. 1. Note carrier wafer 1001 with release layer 1003 and sacrificial (etch stop) layer 1005. FIG. 1 thus depicts a carrier wafer after deposition of 1003, 1005 and planarization. FIG. 2 depicts bonding of a chiplet 1009 using bonding layer/film 1007. “Chiplet” is used in its ordinary sense to refer to a small, modular chip that performs a specific function such as a processor core, a memory block, an I/O driver, a signal processing unit, or the like. Chiplet 1009 can have typical FEOL/MOL/BEOL structures (for a functional die). FIG. 2 depicts representative chiplet structures and other embodiments could have other features. Element 1008 represents an electrical connection for the chiplet (chiplet contact pad 1008).

The chiplet 1009 can include a silicon substrate or any other suitable substrate. It can be semiconductor (including compound semiconductors). It could even be an insulator, such as glass or polymer. Furthermore, while a chiplet 1009 is depicted in the non-limiting example, embodiments can generally include a variety of chips/chiplets, functional or passive components (inductors, capacitors, resistors), or could even be an integrated voltage regulator or the like.

Bonding layer/film 1007 may be one or more layers, as is typical. Note also that element 1007 is shown as a continuous layer across sacrificial (etch stop) layer 1005; however, it may be only under the chiplet 1009, depending on the process. Bonding can be, for example, an oxide-oxide bond or any other direct bonding method. Bonding could also be done with polymers or the like. A typical approach in industry is a die attach film (thin film adhesive).

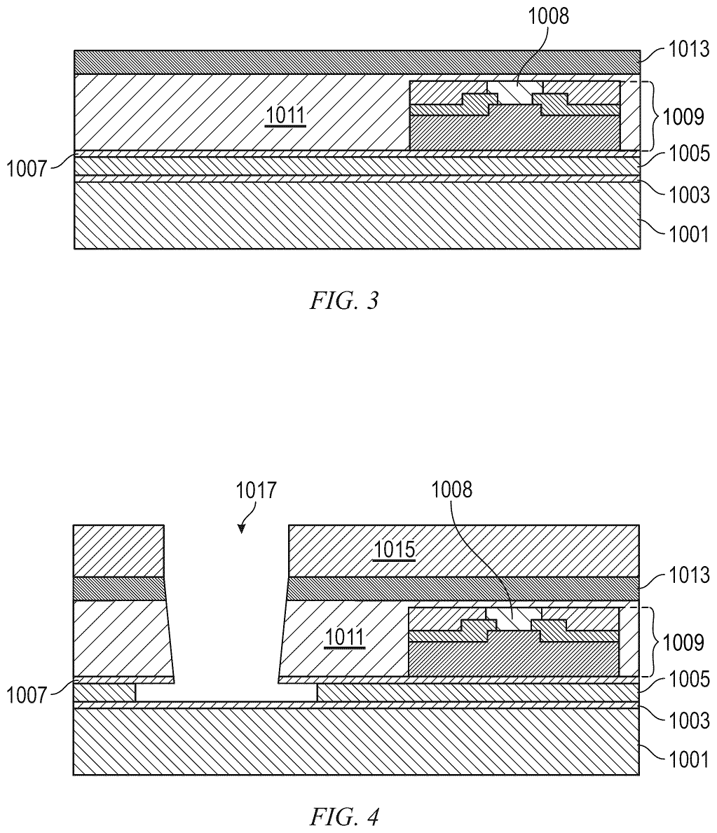

FIG. 3 depicts deposition and planarization of, e.g., a hard dielectric 1011 (not necessarily a hard dielectric (oxide, nitride, etc.); could be inorganic dielectrics as well, such as polymers, molding compound, epoxies, etc., and can be one or more layers of any of the exemplary materials) as well as deposition and planarization of additional metal 1013. Note that the metal plate is shown deposited before via etch, which is one non-limiting option. An alternate option is to carry out the via etch first, fill the via (forming inner and outer metal layers), then recess the dielectric around the top of the via (exposing the edge of the outer metal cladding), and then form a metal plate/line through additive or subtractive processes (which effect the sidewall profile of the metal line).

A pertinent aspect in one or more embodiments is the undercut footing for a coaxial via. FIG. 4 shows deposition of, e.g., a hard mask 1015 (could be a hard mask or resist mask depending on etch requirements) as well as patterning same for coaxial TIV formation and etch stop layer etching (including lateral etch)—the resulting cavity is designated as 1017. Etch stop layer 1005 is etched away down to release layer 1003. In one or more embodiments, element 1005 is flat due to being deposited on a flat surface. In some instances, if bonding layer/film 1007 is present everywhere it can function as an etch stop as well, or there can be another layer present above etch stop layer 1005 that serves as an etch stop, but is not necessarily required, depending on the etch selectivity of the materials and the material stack.

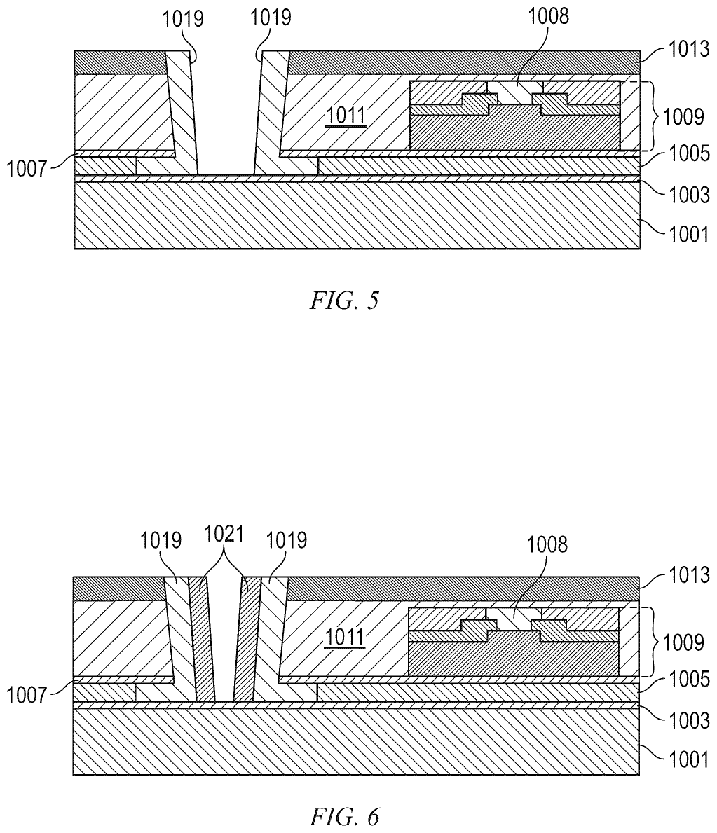

In FIG. 5, remove the hard mask, deposit additional metal 1019, and break through same down to the release layer 1003. There can also be an optional layer above release layer 1003 so that the release layer does not get damaged during processing. In FIG. 6, deposit dielectric layer 1021, and break through same down to the release layer 1003.

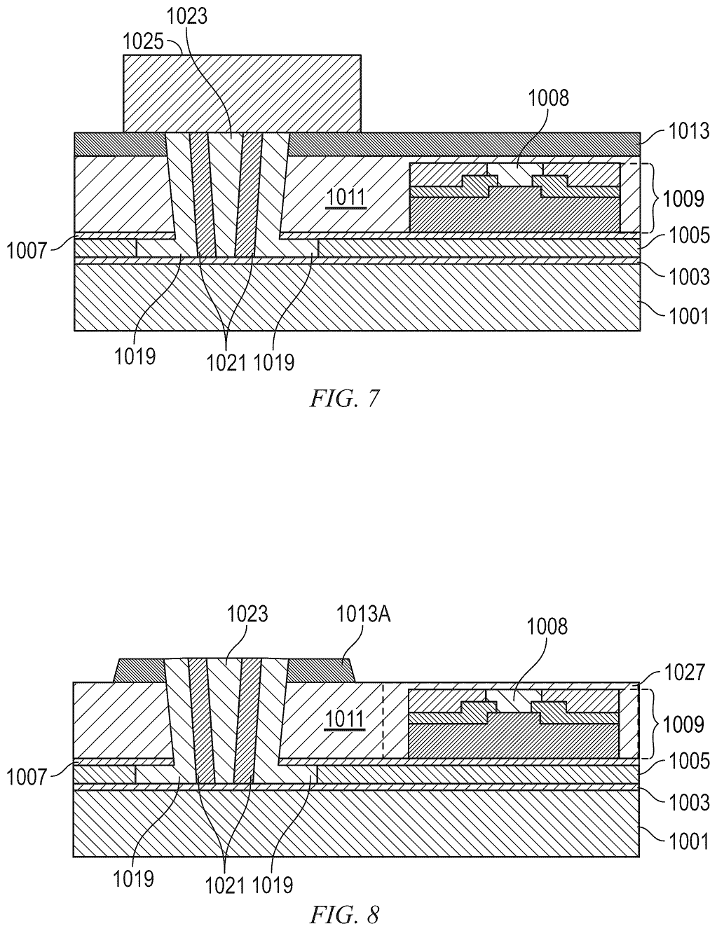

In FIG. 7, deposit metal 1023. Note also deposition and patterning of additional hard mask 1025 for the TIV top footing. The coaxial TIV includes center conductor (metal 1023) and outer conductor (metal 1019). Note that the presence of metal for the top footing can alternatively be introduced later. A damascene or subtractive process could be employed, for example, which influences the sidewall profile of the metal feature(s).

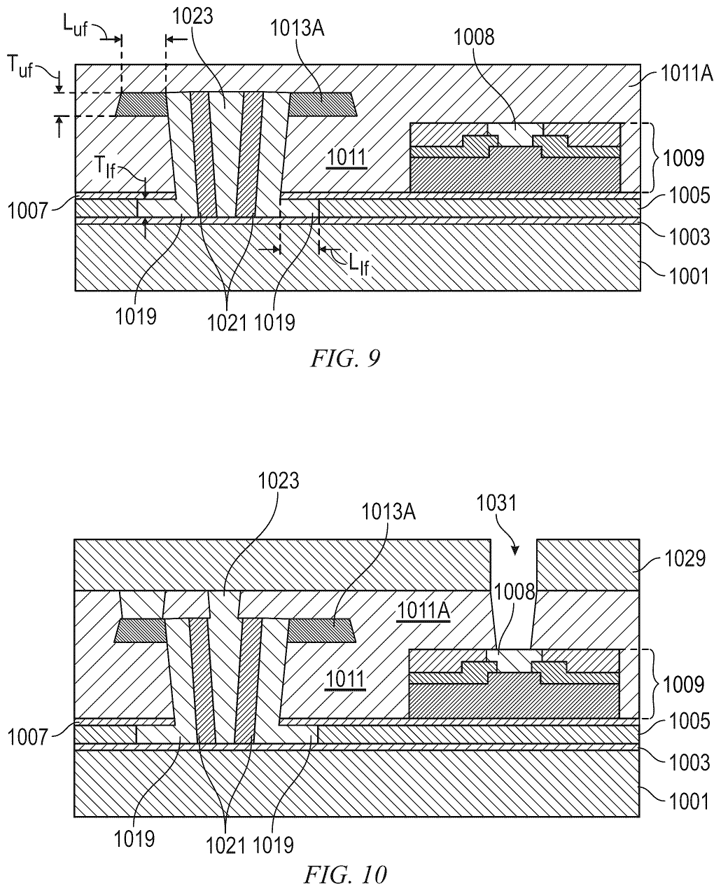

FIG. 8 shows an alternative technique for forming the top footing by subtractive etching. In this aspect, form the TIV 1019, 1021, 1023 first; then, etch the hard dielectric 1011 to form a trench 1027 for the chiplet, and then attach the chiplet 1009 after the TIV formation. Here, the trench is represented by the dotted box 1027. In this case, there can be a die attach film to join the chiplet in the trench, and then the trench can be provided with a dielectric fill, which could, for example, include one or more different films than the depicted element 1011. Metal 1013A is what remains after etching the metal 1013 that is not protected by the hard mask 1025 (in either the main or alternative techniques). In FIG. 9, remove the hard mask 1025, fill with additional hard dielectric 1011A (or other material as discussed above), and planarize. In one or more embodiments, the thickness of the footings is ˜100 nm and the length of the footing is ˜500 nm; however, any appropriate footing thickness and length can be employed. The thicker the metal is, the bigger the cross section for current flow, and thus, the lower the resistance. The exemplary footing thickness of 100 nm (or above) is selected to help reach a reasonable resistance. If desired, the footing can be significantly thicker than 100 nm as well; the footing can even be on the order of microns thick, depending on the ability to fill the footing. A range of different thicknesses and lengths are possible. In the FEOL, these kinds of structures can be very thin, on the order of tens of nm. However, in a packaging aspect, they can typically be at least 1-2 μm thick. In FIG. 9, the thickness of the topmost footing is designated as T_{uf}, the thickness of the lowermost footing is designated as T_{lf}, the length of the topmost footing is designated as L_{uf}, and the thickness of the lowermost footing is designated as L_{lf}. The exemplary thickness and length values are equally applicable to both the topmost and lowermost footings, which can, in general, have the same or different length and width values.

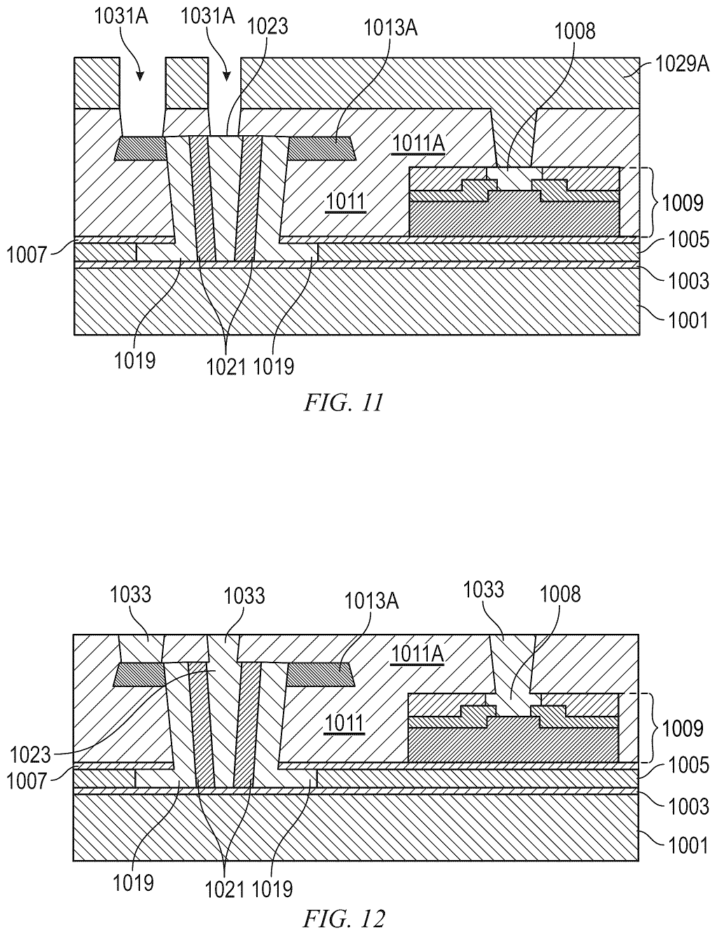

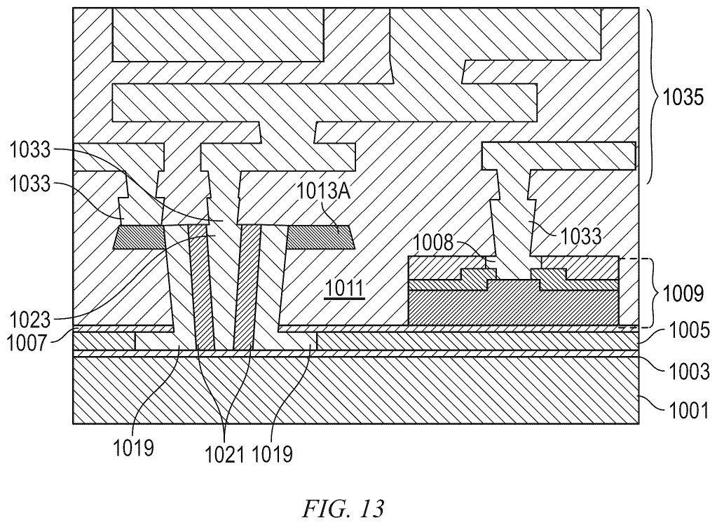

In FIG. 10, deposit and pattern photoresist 1029, then etch to form cavity 1031 for a contact via to the contact 1008 on the chiplet. In FIG. 11, deposit additional photoresist, filling cavity 1031, and pattern same for additional contact vias 1031A at the coaxial TIV; the photoresist remaining after this is designated as 1029A. In FIG. 12, remove the photoresist, carry out metallization to obtain the contact vias 1033, and planarize. As shown at 1035 in FIG. 13, deposit additional metal and dielectric to form additional vertical vias and horizontal lines as are appropriate for the given application. The skilled artisan, given the teachings herein, will be able to adopt known techniques to accomplish same.

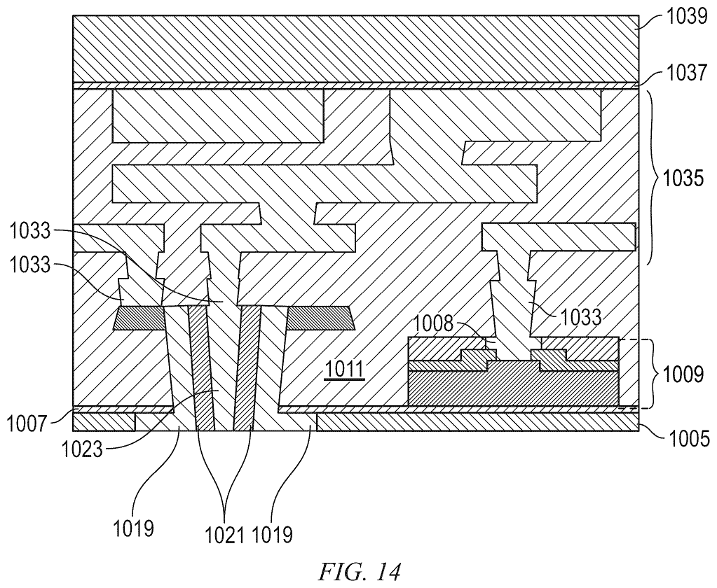

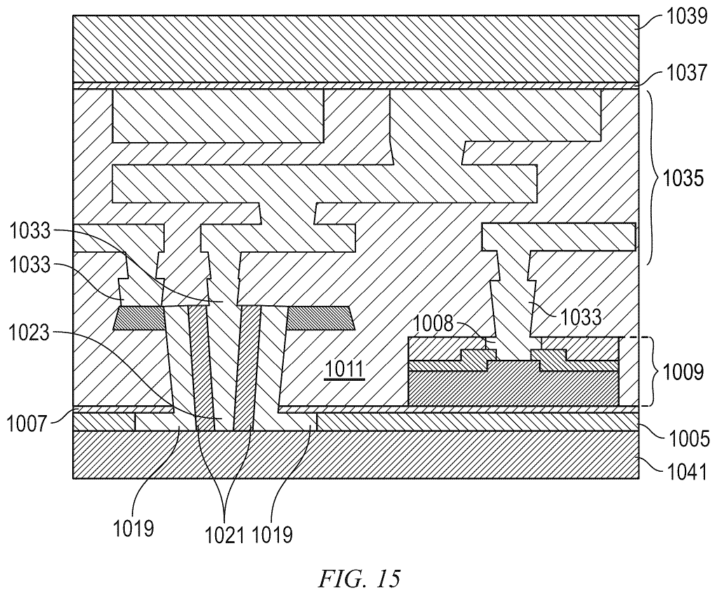

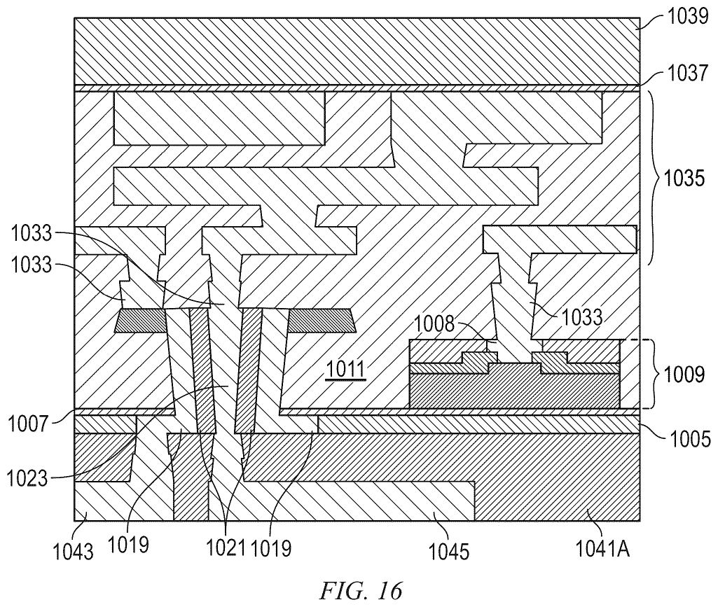

Several different approaches can be employed to proceed further from the structure depicted in FIG. 13. In a first exemplary approach, referring to FIG. 14, bond on a second carrier wafer 1039 using one or more bonding films 1037, flip the structure (flipping is not shown in the drawings but is familiar to the skilled artisan from so-called flip chip processing/wafer level fanout processing), and remove carrier wafer 1001 and release layer 1003 on the opposite side in a carrier debonding process. The carrier is optional, depending on the thickness of elements 1035 and 1009/1011. In FIG. 15 deposit and planarize hard dielectric 1041 as shown (generally, hard dielectric (oxide, nitride, etc.) or organic dielectric or the like). In FIG. 16, carry out ground and signal via patterning and metallization, and additional metal line patterning and metallization, to obtain ground line/via 1043 connected to the TIV outer conductor and signal line/via 1045 connected to the TIV inner conductor 1023. Note that element 1041 is shown thicker and designated as 1041A in FIG. 16 so that it can accommodate the 1043, 1045 structure after RIE or the like to clear out the space needed. There can be multiple layers of dielectric, which can be applied with each via or line layer, and layers can be of different materials. To avoid clutter, the element is simply designated as 1041A in FIG. 16, with the understanding that different layers could be present.

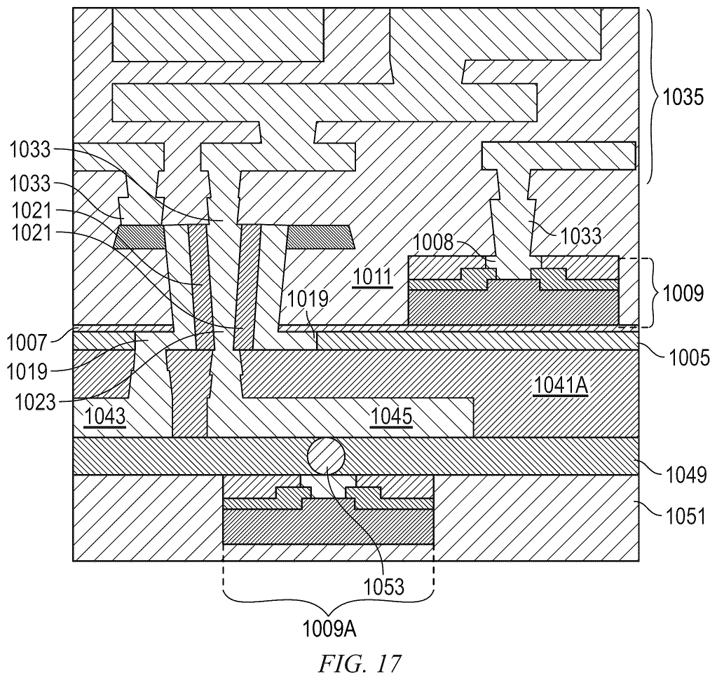

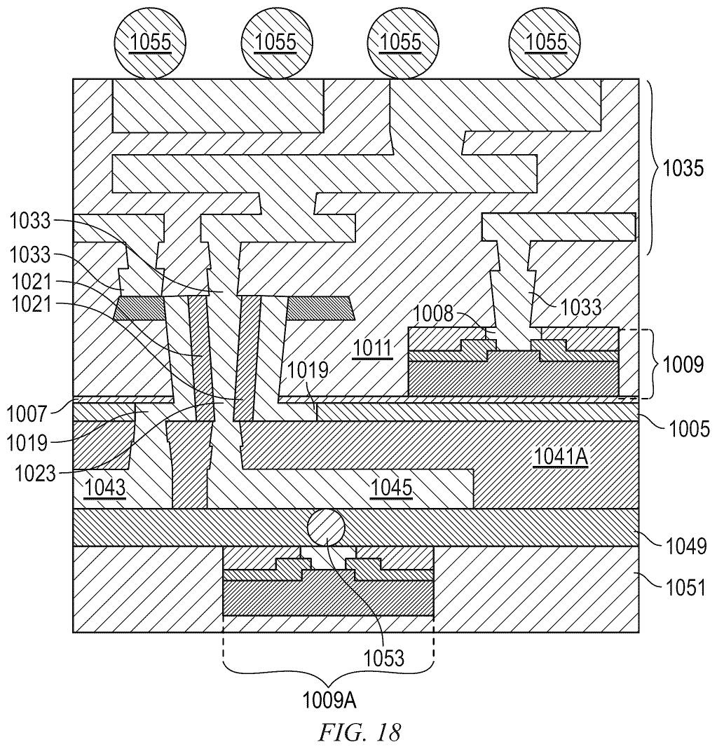

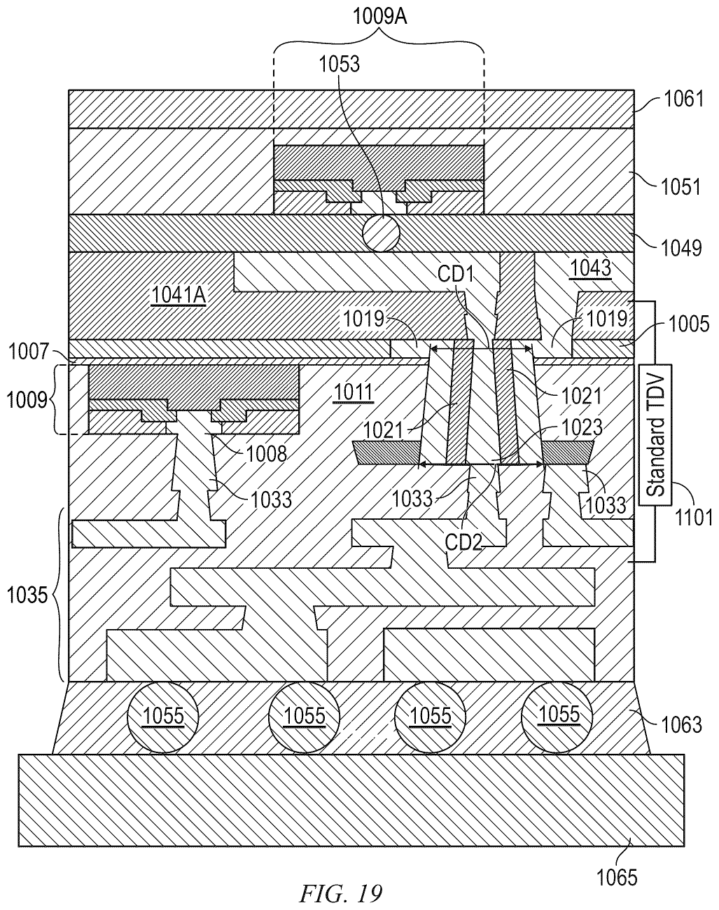

In FIG. 17, bond an additional chiplet 1009A with a micro C4 (C4=controlled-collapse chip connection) bump 1053 (or other bonding) and underfill 1049, molding 1051, and planarization. Also, remove the second carrier wafer 1039 and bonding film 1037; the chiplet 1009A is bonded to the opposite side from where the second carrier wafer 1039 was removed. Micro bumps are a non-limiting example of interconnects. Any suitable interconnect structure, solder, Cu—Cu bonding, hybrid bonding, etc., can be employed. In FIG. 18, form C4 bumps 1055 (again, a non-limiting example of interconnects). In FIG. 19, attach to the package (generally, package, organic interposer, laminate, silicon interposer, printed circuit board (PCB), or the like) 1065 using C4 bumps 1055 (or other interconnects) and apply underfill 1063. Note also the package lid 1061. The lid is shown simplistically for illustrative convenience, but typically will encapsulate the full chip structure and contact the top surface of the package. Advantageously, this flow can optionally be employed for a top chip 1009A that is more valuable/expensive/fragile than chip 1009, allowing chip 1009A to be attached last, reducing the chance for damage to the more valuable/expensive/fragile chip during processing.

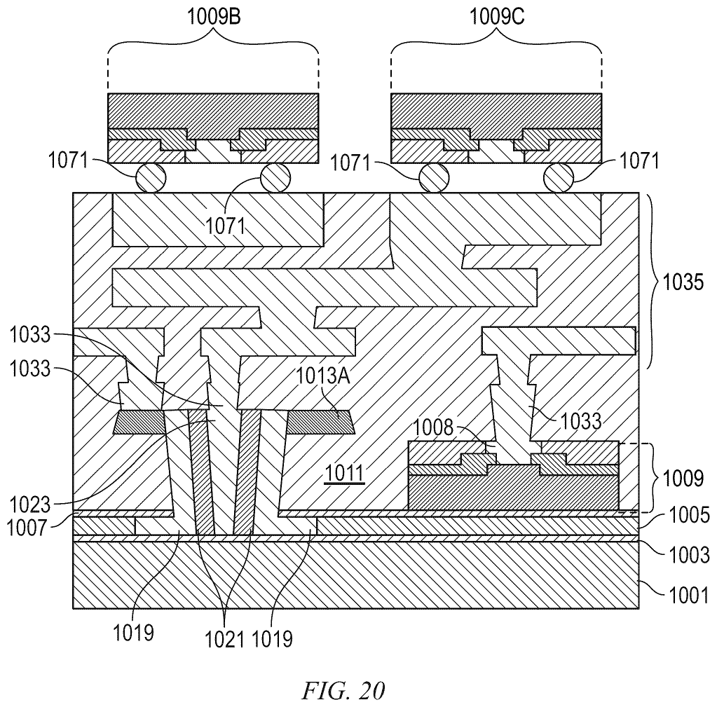

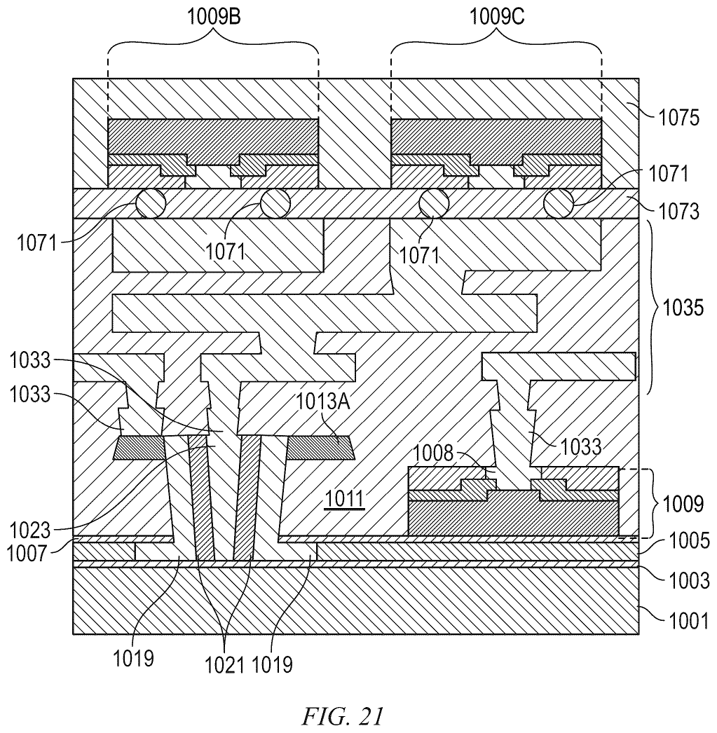

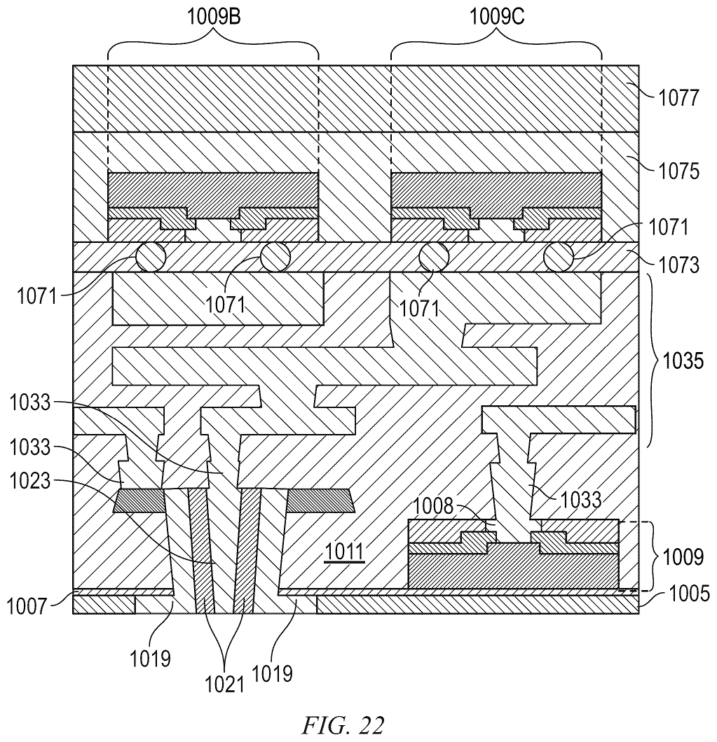

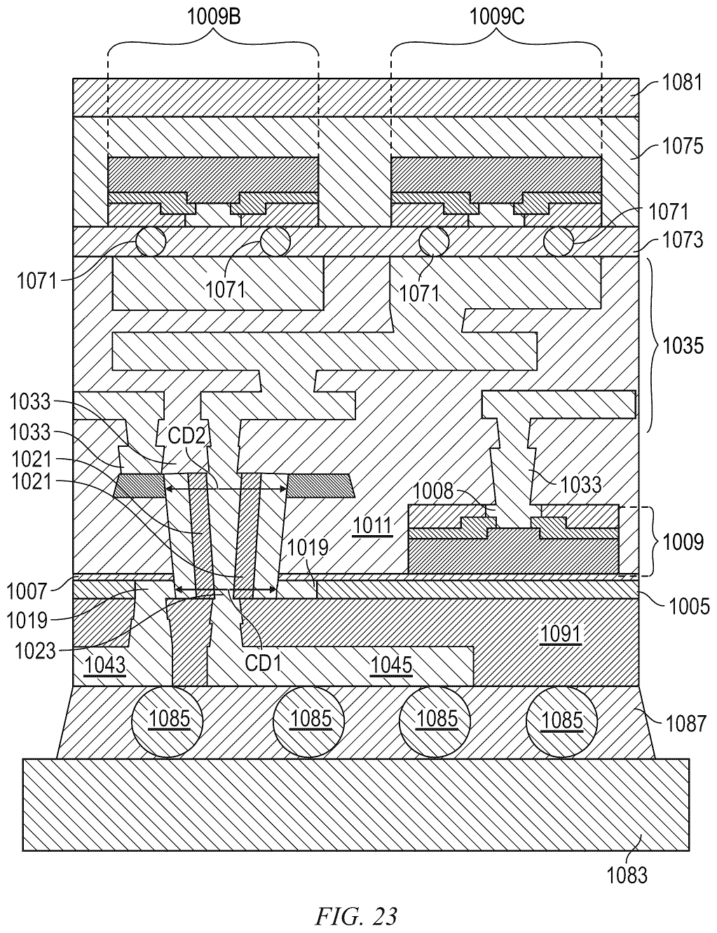

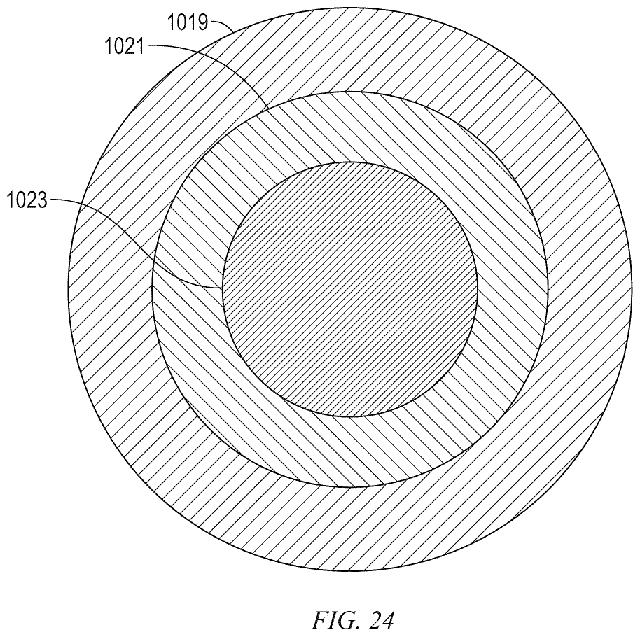

As noted, several different approaches can be employed to proceed further from the structure depicted in FIG. 13. In a second exemplary approach, referring to FIG. 20, starting with the structure depicted in FIG. 13, use mini C4 bumps 1071 to attach additional chiplets 1009B and 1009C. In FIG. 21, deposit underfill 1073 and molding 1075. In FIG. 22, de-bond the bottom carrier 1001 and release layer 1003; optionally, if the size of the space allows, an additional carrier 1077 can be added. Furthermore in this regard, if the existing structure (chips, wiring/dielectric) is thick enough, it is possible that that the tools can handle the substrate without an additional carrier. In FIG. 23, carry out steps similar to FIGS. 15, 16, 18, and 19, removing the additional carrier 1077 if present, to obtain the depicted structure. Note package lid 1081, ground line/via 1043 connected to the TIV outer conductor and signal line/via 1045 connected to the TIV inner conductor, hard dielectric 1091, C4 bumps 1085, package 1083, and underfill 1087.

Thus, one or more embodiments include process steps including providing a carrier wafer with etch stop layer deposition and planarization; chiplet bonding; hard dielectric deposition and planarization, additional metal deposition and planarization; coaxial TIV patterning and etch stop layer etch (including lateral etch); hard mask removal, metal layer deposition and break through; dielectric layer deposition and break through; and metal deposition and breakthrough, TIV top footing patterning. Optionally, a subtractive top footing etch can be used instead. One or more embodiments further include hard mask removal, dielectric fill and planarization; contact via patterning at the chiplet; additional contact via patterning at the coaxial TIV; photoresist removal, via metallization, and planarization; and additional metal via and line patterning.

The first exemplary approach discussed above can include, for example, carrier wafer bonding, wafer flip, and opposite side carrier de-bond; hard dielectric deposition and planarization; ground and signal via patterning and metallization, additional metal line patterning and metallization; additional chiplet bond with micro C4 bump and underfill, molding and planarization, carrier de-bond and bonding to the opposite side; C4 bump formation; and attachment to the package/PCV.

In another aspect, an exemplary semiconductor device includes a coaxial through dielectric via (TIV) with outside metal cladding connected to a top and bottom footing structure. This footing structure is connected, for example, to one kind of power terminal, while the middle metal cladding is connected to a signal terminal. In some cases, a chiplet is adjacent to the TIV.

Optionally, a sacrificial layer is adjacent to at least one footing.

Optionally, a trench is adjacent to the coaxial TIV for chiplet attachment.

Optionally, at least one chiplet is stacked adjacent to a coaxial TIV.

Optionally, a chiplet is connected to the coaxial TIV.

Optionally, the coaxial TIV has a first side with a first critical dimension CD1 and a second side with a second critical dimension CD2, where CD1<CD2—see FIGS. 19 and 23. The package can be attached to interconnects that are connected to the first side, as in FIG. 23, or to interconnects that are connected to the second side, as in FIG. 19.

Referring to FIG. 24, which shows a cross-section through the via perpendicular to the long axis thereof, and is equally applicable to the first and second embodiments, in a non-limiting example, the coaxial via is circular in cross-section and the first and second critical dimensions are diameters. Other embodiments could have different cross sections and the CDs could be widths or other dimensions instead of diameters.

In one or more embodiments, a coaxial TIV contacts footings on its top and bottom sides for easier ground and signal input. One or more embodiments include a continuous angled extension to contact with the signal and ground. In one or more embodiments, the footings/extensions provides one or both of: making the connection toward the ground and signal much easier; and forming a continuous barrier for de-coupling from nearby devices due to the shielding effect of metal. Thus, advantageously, in one or more embodiments, there is a connection to the signal and ground metal from both sides of the via (top and bottom), and/or there is a footing structure that is made with an undercut process using a sacrificial material that still partially remains in the final structure. A pertinent aspect in one or more embodiments is that the horizontal footing is extended, which makes the connection more flexible. Meanwhile, it also better shields from noise.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with conventional techniques that can be adapted to form the starting structure, and with conventional techniques, such as lithography and etching, that can be adapted to carry out the patterning. The skilled artisan will be familiar with suitable materials for insulators (e.g., SiO₂), metallization (e.g., copper with liners/barriers such as Ta, TaN), and the like.

Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary semiconductor structure include a first wiring region 1035 including a plurality of interconnected first metal lines and first vias; an insulator portion 1011 outward of the first wiring region; and a first circuitry element 1009, located in the insulator portion, and connected to at least a first one of the first vias in the first wiring region. The first circuitry element can be the chiplet 1009, which can include a silicon substrate or any other suitable substrate; a semiconductor (including compound semiconductors); an insulator, such as glass or polymer; furthermore, while a chiplet 1009 is depicted in the non-limiting example, embodiments can generally include a variety of chips/chiplets, functional or passive components (inductors, capacitors, resistors), or could even be an integrated voltage regulator or the like. Also included is a coaxial through dielectric via 1019, 1021, 1023 located in the insulator portion. The coaxial through dielectric via includes an inner conductor, a dielectric layer surrounding the inner conductor, and an outer conductor outward of the dielectric layer. The outer conductor includes inner and outer footing structures. A second wiring region is outward of the insulator portion, and the second wiring region includes a signal line 1045 connected to the inner conductor and a power line 1043 connected to the outer footing structure of the outer conductor. Ground terminals, a signal source, and a power/voltage/current source can also be provided as appropriate. The inner conductor is connected to at least a second one of the first vias in the first wiring region and the inner footing structure of the outer conductor is connected at least a third one of the first vias in the first wiring region.

Note that the outer cladding layer that also fill the undercut can be one or more metal layers; or the dielectric between core and cladding could be one or more layers; or the cladding and core could be different metals, based on the metal fill requirements.

Referring to the discussion of thickness and length of the footings with respect to FIG. 9, in some cases, the inner footing structure has an inner footing structure thickness and an inner footing structure length; and the outer footing structure has an outer footing structure thickness and an outer footing structure length. For example, the inner footing thickness is at least 100 nm; and the outer footing thickness is at least 100 nm.

In one or more embodiments, the inner footing length is greater than the inner footing thickness; and the outer footing length is greater than the outer footing thickness. For example, the inner footing length is at least 500 nm; and the outer footing length is at least 500 nm.

One or more embodiments further include sacrificial (etch stop) layer 1005 adjacent to the outer footing structure of the outer conductor.

As shown in FIG. 8, optionally, the first chiplet is located in a trench 1027 defined in the insulator portion.

Referring for example to FIG. 19, in some cases, the outer conductor tapers from a larger critical dimension CD2 adjacent the first wiring region to a lower critical dimension CD1 adjacent the second wiring region.

Referring specifically to the first non-limiting exemplary embodiment, in one or more instances, a package is coupled to the first wiring region. Some cases further include a second circuitry element located outward of the second wiring region and coupled to the signal line. The second circuitry element can be a second chiplet or otherwise as discussed above. A lid can be outward of the second chiplet.

Referring specifically to the second non-limiting exemplary embodiment, in one or more instances, a semiconductor structure further includes a package coupled to the second wiring region. Optionally, a second circuitry element is located inward of the first wiring region and coupled to at least one of the plurality of interconnected first metal lines. The second circuitry elements can include a second chiplet or otherwise as discussed above.

One or more examples further include a lid inward of the second chiplet.

One or more embodiments further include a standard (single conductor) through-dielectric via 1101 adjacent to the co-axial through-dielectric via (e.g., since there can be power vias that do need the coax structure). This aspect is shown schematically in FIG. 19, with generalized connections to wiring in 1011, 1041A.

In the following discussion of exemplary methods, chiplets are non-limiting examples of circuitry elements. Given the discussion thus far, it will further be appreciated that, in general terms, an exemplary method of forming a semiconductor structure (e.g., non-trench method, provides starting point for embodiment 1 or embodiment 2) includes providing an initial structure including a carrier wafer, a sacrificial layer outward of the carrier, an insulator region outward of the sacrificial layer, a first chiplet in the insulator region, and a metal layer outward of the insulator region, as per FIG. 3; using a first patterned mask, etching to produce a through dielectric via formation region in the metal layer and the insulator region, and a first footing formation region in the sacrificial layer, as per FIG. 4; and metallizing the first footing formation region and walls of the through dielectric via formation region to produce an outer conductor (FIG. 5). Further steps include forming a dielectric layer on the metallized walls of the through dielectric via formation region (FIG. 6); forming a through dielectric via inner conductor within the dielectric layer on the metallized walls, and, using a second patterned mask, etching to produce second footings from the metal layer (FIGS. 7 and 8 (FIG. 8 footings only not trench)); and forming a first supplemental wiring region outward of the metal layer and the insulator region, with connections to the first chiplet, the inner conductor, and the outer conductor (FIGS. 9-13).

To form embodiment 1 starting with the non-trench method, further steps include forming a second supplemental wiring region (FIGS. 14-16), including a signal line connected to the inner conductor and a power line connected to the outer conductor; attaching a second chiplet to the signal line (FIG. 17); and attaching a lid over the second chiplet and securing the first supplemental wiring region to a package (FIGS. 18 and 19).

To form embodiment 2 starting with the non-trench method, further steps include connecting a second chiplet to the first supplemental wiring region (FIGS. 20-22, there can be multiple additional chiplets/elements); securing a lid over the second chiplet (FIG. 23); forming a second supplemental wiring region, including a signal line connected to the inner conductor and a power line connected to the outer conductor (FIG. 23); and coupling a package to the second supplemental wiring region (FIG. 23).

Given the discussion thus far, it will further be appreciated that, in general terms, another exemplary method of forming a semiconductor structure (e.g., trench method, provides starting point for embodiment 1 or embodiment 2) includes providing an initial structure including a carrier wafer, a sacrificial layer outward of the carrier, an insulator region outward of the sacrificial layer, and a metal layer outward of the insulator region (FIG. 3 without chiplet); using a first patterned mask, etching to produce a through dielectric via formation region in the metal layer and the insulator region, and a first footing formation region in the sacrificial layer (FIG. 4 without chiplet); metallizing the first footing formation region and walls of the through dielectric via formation region to produce an outer conductor (FIG. 5 without chiplet); forming a dielectric layer on the metallized walls of the through dielectric via formation region (FIG. 6 without chiplet); forming a through dielectric via inner conductor within the dielectric layer on the metallized walls, and, using a second patterned mask, etching to produce second footings from the metal layer (FIG. 7 without chiplet and FIG. 8); forming a trench in the insulator region and locating a first chiplet in the trench (FIG. 8); and forming a first supplemental wiring region outward of the metal layer and the insulator region, with connections to the first chiplet, the inner conductor, and the outer conductor (FIGS. 9-13).

To form embodiment 1 starting with the trench method, further steps include forming a second supplemental wiring region (FIGS. 14-16), including a signal line connected to the inner conductor and a power line connected to the outer conductor; attaching a second chiplet to the signal line (FIG. 17); and attaching a lid over the second chiplet and securing the first supplemental wiring region to a package (FIGS. 18 and 19).

To form embodiment 2 starting with the trench method, further steps include connecting a second chiplet to the first supplemental wiring region (FIGS. 20-22, there can be multiple additional chiplets/elements); securing a lid over the second chiplet (FIG. 23); forming a second supplemental wiring region, including a signal line connected to the inner conductor and a power line connected to the outer conductor (FIG. 23); and coupling a package to the second supplemental wiring region (FIG. 23).

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of the disclosed coaxial TIVs with a lateral metal footing connection for chiplet power signal connection.

An integrated circuit in accordance with aspects of the present inventions can be employed in essentially any application and/or electronic system where one or more aspects of the disclosed coaxial TIVs with a lateral metal footing connection for chiplet power signal connection would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a first wiring region including a plurality of interconnected first metal lines and first vias;
an insulator portion outward of the first wiring region;
a first circuitry element, located in the insulator portion, and connected to at least a first one of the first vias in the first wiring region;
a coaxial through dielectric via located in the insulator portion, the coaxial through dielectric via including an inner conductor, a dielectric layer surrounding the inner conductor, and an outer conductor outward of the dielectric layer, the outer conductor including inner and outer footing structures; and
a second wiring region outward of the insulator portion, the second wiring region including a signal line connected to the inner conductor and a power line connected to the outer footing structure of the outer conductor;
wherein the inner conductor is connected to at least a second one of the first vias in the first wiring region and the inner footing structure of the outer conductor is connected at least a third one of the first vias in the first wiring region.

2. The semiconductor structure of claim 1, wherein:
the inner footing structure has an inner footing structure thickness and an inner footing structure length; and
the outer footing structure has an outer footing structure thickness and an outer footing structure length.

3. The semiconductor structure of claim 2, wherein:
the inner footing thickness is at least 100 nm; and
the outer footing thickness is at least 100 nm.

4. The semiconductor structure of claim 3, wherein:
the inner footing length is greater than the inner footing thickness; and
the outer footing length is greater than the outer footing thickness.

5. The semiconductor structure of claim 4, wherein:
the inner footing length is at least 500 nm; and
the outer footing length is at least 500 nm.

6. The semiconductor structure of claim 2, wherein the first circuitry element comprises a first chiplet.

7. The semiconductor structure of claim 6, further comprising sacrificial (etch stop) layer adjacent to the outer footing structure of the outer conductor.

8. The semiconductor structure of claim 6, wherein the first chiplet is located in a trench defined in the insulator portion.

9. The semiconductor structure of claim 6, wherein the outer conductor tapers from a larger critical dimension adjacent the first wiring region to a lower critical dimension adjacent the second wiring region.

10. The semiconductor structure of claim 9, further comprising a package coupled to the first wiring region.

11. The semiconductor structure of claim 10, further comprising a second circuitry element located outward of the second wiring region and coupled to the signal line.

12. The semiconductor structure of claim 11, wherein the second circuitry element comprises a second chiplet.

13. The semiconductor structure of claim 12, further comprising a lid outward of the second chiplet.

14. The semiconductor structure of claim 9, further comprising a package coupled to the second wiring region.

15. The semiconductor structure of claim 14, further comprising a second circuitry element located inward of the first wiring region and coupled to at least one of the plurality of interconnected first metal lines.

16. The semiconductor structure of claim 15, wherein the second circuitry elements comprises a second chiplet.

17. The semiconductor structure of claim 16, further comprising a lid inward of the second chiplet.

18. The semiconductor structure of claim 1, further comprising a standard through-dielectric via adjacent to the co-axial through-dielectric via.

19. A method of forming a semiconductor structure, comprising:
providing an initial structure including a carrier wafer, a sacrificial layer outward of the carrier, an insulator region outward of the sacrificial layer, a first circuitry element in the insulator region, and a metal layer outward of the insulator region;
using a first patterned mask, etching to produce a through dielectric via formation region in the metal layer and the insulator region, and a first footing formation region in the sacrificial layer;
metallizing the first footing formation region and walls of the through dielectric via formation region to produce an outer conductor;
forming a dielectric layer on the metallized walls of the through dielectric via formation region;
forming a through dielectric via inner conductor within the dielectric layer on the metallized walls, and, using a second patterned mask, etching to produce second footings from the metal layer; and
forming a first supplemental wiring region outward of the metal layer and the insulator region, with connections to the first circuitry element, the inner conductor, and the outer conductor.

20. A method of forming a semiconductor structure, comprising:
providing an initial structure including a carrier wafer, a sacrificial layer outward of the carrier, an insulator region outward of the sacrificial layer, and a metal layer outward of the insulator region;
using a first patterned mask, etching to produce a through dielectric via formation region in the metal layer and the insulator region, and a first footing formation region in the sacrificial layer;
metallizing the first footing formation region and walls of the through dielectric via formation region to produce an outer conductor;
forming a dielectric layer on the metallized walls of the through dielectric via formation region;
forming a through dielectric via inner conductor within the dielectric layer on the metallized walls, and, using a second patterned mask, etching to produce second footings from the metal layer;
forming a trench in the insulator region and locating a first circuitry element in the trench;
forming a first supplemental wiring region outward of the metal layer and the insulator region, with connections to the first circuitry element, the inner conductor, and the outer conductor.
